(19) United States
(12) Patent Application Publication
(10) Pub. No.: US 2026/0255469 A1
(43) Pub. Date: Aug. 27, 2026

(54) BANDWIDTH ENHANCEMENT FOR DATA STORAGE DEVICES HAVING FLIP CHIP MEMORY DIES

(71) Applicant: Sandisk Technologies, Inc., Milpitas, CA (US)

(72) Inventors: Vijay Kumar Singh, Bengaluru (IN); Abhishekh M L, Bengaluru (IN); Tamilharasan, Dharmapuri (IN)

(21) Appl. No.: 19/059,984

(22) Filed: Feb. 21, 2025

(51) Int. Cl. H05K 1/02; H05K 1/18

(52) U.S. Cl. CPC H05K 1/0219; H05K 1/18; H05K 2201/0776; H05K 2201/10159; H05K 2201/10674

(57) ABSTRACT

A data storage device includes a plurality of flip chip memory dies horizontally arranged on one or more surfaces of a PCB. The flip chip memory dies are coupled to a controller of the data storage device using variable impedance traces. A first portion of one variable impedance trace has a first impedance while a second portion of the variable impedance trace has a second impedance. The difference in impedance between the portions of the variable impedance trace is based, at least in part, on a configuration of one or more metal layers in the PCB. A resistor is placed between a first memory die of the plurality of memory dies and a second memory of the plurality of memory dies and is also used to increase an impedance of at least one of the portions of the variable impedance trace.

### BACKGROUND

A data storage device, such as a NAND data storage device, typically includes a number of vertically stacked memory dies. Bond wires form connections between each memory die. The stack of memory dies is placed inside ball grid array (BGA) package and the BGA package is coupled to a printed circuit board (PCB). This configuration enables high performance in terms of capacity and bandwidth.

However, assembling data storage devices in this manner is very complex and time consuming. While there may be less complex assembly configurations, such as using flip chip memory dies in lieu of vertically stacked memory dies, these solutions do not provide the same performance characteristics.

Accordingly, it would be beneficial for a data storage device without vertically stacked memory dies to have the same performance characteristics, or better performance characteristics, than data storage devices with vertically stacked memory dies.

### SUMMARY

The present disclosure describes a data storage device having a plurality of memory dies horizontally arranged on one or more surfaces of a printed circuit board (PCB) of the data storage device. In an example, the plurality of memory dies are flip chip memory dies. The plurality of flip chip memory dies are coupled to a controller of the data storage device using various variable impedance traces. In an example, a first portion at least one variable impedance trace of the plurality of variable impedance traces has a first impedance while a second portion of the variable impedance trace has a second impedance. The difference in impedance between the various portions of the variable impedance traces is based, at least in part, on a configuration and/or layout of one or more metal layers in the PCB.

In addition to the above, a discrete component, such as a resistor, is placed between a first memory die of the plurality of memory dies and a second memory of the plurality of memory dies. The discrete component is also used to increase an impedance of at least one variable impedance trace of the plurality of variable impedance traces.

Accordingly, examples of the present disclosure describe a semiconductor package that includes PCB and a controller mounted on the PCB. A plurality of flip chip semiconductor dies are mounted on the PCB. A plurality of variable impedance traces electrically couple the controller to the plurality of flip chip semiconductor dies. In an example, a component is positioned between a first flip chip semiconductor die in the plurality of flip chip semiconductor dies and a second flip chip semiconductor die in the plurality of flip chip semiconductor dies. The component increases a resistance of at least a portion of at least one variable impedance trace of the plurality of variable impedance traces between the first flip chip semiconductor die and the second flip chip semiconductor die.

Examples also describe a data storage device that includes a PCB having a plurality of metal layers. In an example, at least one metal layer of the plurality of metal layers includes one or more gaps. A controller is mounted on the PCB as are a plurality of memory dies. For example, the plurality of memory dies are horizontally arranged on the PCB. A plurality of traces electrically couple the controller to the plurality of memory dies and are at least partially positioned over the one or more gaps. A resistor is positioned between a first memory die in the plurality of memory dies and a second memory die in the plurality of memory dies.

Still other examples describe a data storage device that includes a PCB. A control means is mounted on the PCB as are a plurality of flip chip data storage means. A plurality of variable impedance signal means electrically couple the control means to the plurality of flip chip data storage means. In an example, a resistance is means positioned between a first flip chip storage means in the plurality of flip chip storage means and a second flip chip storage means in the plurality of flip chip storage means.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1A illustrates a data storage device having a plurality of memory dies horizontally arranged on a first side of a PCB according to an example.

FIG. 1B illustrates the data storage device of FIG. 1A having a plurality of memory dies horizontally arranged on a second side of the PCB according to an example.

FIG. 2A illustrates a first variable impedance trace coupling the controller to the first group of memory dies of the data storage device and a second variable impedance trace coupling the controller to the second group of memory dies of the data storage device according to an example.

FIG. 2B illustrates a third variable impedance trace coupling the controller to the third group of memory dies of the data storage device and a fourth variable impedance trace coupling the controller to the fourth group of memory dies of the data storage device according to an example.

FIG. 3A illustrates a first discrete component being added to, or associated with, the first variable impedance trace of the data storage device of FIG. 2A and a second discrete component being added to, or associated with, the second variable impedance trace of the data storage device of FIG. 2A according to an example.

FIG. 3B illustrates a third discrete component being added to, or associated with, the third variable impedance trace of the data storage device of FIG. 2B and a fourth discrete component being added to, or associated with, the fourth variable impedance trace of the data storage device of FIG. 2B according to an example.

FIG. 4 illustrates a partial side view of the data storage device of FIG. 1A according to an example.

FIG. 5A illustrates a side view of the PCB of the data storage device of FIG. 1A according to an example.

FIG. 5B illustrates the various metal layers of the PCB of FIG. 5A according to an example.

FIG. 5C illustrates the various metal layers of the PCB of FIG. 5A according to another example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. The following detailed description is therefore not to be taken in a limiting sense, and the scope of the present disclosure is defined by the appended claims and their equivalents.

As previously indicated, data storage devices, such as NAND data storage devices, typically include a number of vertically stacked memory dies. The memory dies are coupled together using various bond wires and the stack of memory dies is placed inside a ball grid array (BGA) package. The BGA package is then coupled to a printed circuit board (PCB). While these memory dies have high performance characteristics in terms of bandwidth and capacity, assembling the memory die stacks is difficult. For example, during a wire bonding process, bond wires are subject to bending or breaking. Additionally, the BGA memory dies increases the cost of manufacturing and assembling the data storage device.

To address the above, the present disclosure describes a data storage device having horizontally arranged memory dies. In an example, the memory dies are NAND memory dies. However, instead of using BGA memory dies, the data storage device described herein includes flip chip memory dies. Although a data storage device and memory dies are mentioned, the concepts described herein are applicable to various semiconductor packages and integrated circuits.

The flip chip memory dies are coupled to a controller of the data storage device using one or more variable impedance traces. For example, a first portion of the variable impedance trace has a first impedance while a second portion of the variable impedance trace has a second impedance. The difference in impedance between the various portions of the variable impedance trace is based, at least in part, on a configuration and/or layout of one or more metal layers in the PCB.

For example, at least one metal layer of the PCB includes an opening or a slot provided underneath at least one of the portions of the variable impedance trace. The opening or slot within the metal layer increases the impedance of the portion of the trace that is located proximate the opening or slot.

In addition to the above, a discrete component, such as a resistor, is placed between a first memory die of the plurality of memory dies and a second memory of the plurality of memory dies. The discrete component is also used to increase an impedance of at least one variable impedance trace, or a portion of the variable impedance trace. The combination of the configuration of the metal layer, the horizontally arranged flip chip memory dies and the configuration of the metal layer, enables the data storage device to have similar, if not better, performance characteristics when compared with data storage devices having vertically stacked memory dies.

In accordance with the above, many technical benefits may be realized including, but not limited to, reducing the cost and complexity of data storage device assembly when compared with current data storage devices having vertically stacked memory dies and maintaining or improving performance benchmarks in terms of bandwidth, capacity, and data valid window margins.

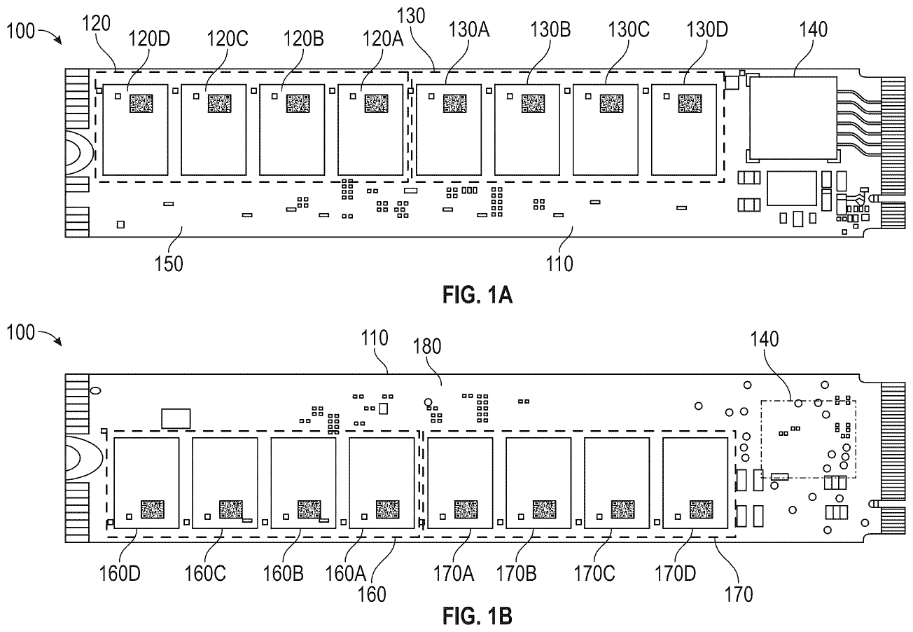

These benefits, along with other examples, will be shown and described in greater detail with respect to FIG. 1-FIG. 5C.

FIG. 1A illustrates a data storage device 100 having a plurality of memory dies horizontally arranged on a first side 150 of a PCB 110 according to an example. For example, the data storage device 100 includes eight memory dies on the first side 150 of the PCB 110 memory die 120A, memory die 120B, memory die 120C, memory die 120D, memory die 130A, memory die 130B, memory die 130C and memory die 130D. Although eight memory dies are shown and described, there may be more than eight memory dies or fewer than eight memory dies on the first side 150 of the PCB 110 of the data storage device 100.

In an example, the data storage device 100 has a four die per channel configuration. For example, the plurality of memory dies are arranged in subsets or groups and each group is associated with a particular channel. For example, memory die 120A, memory die 120B, memory die 120C and memory die 120D form a first group of memory dies 120 and/or are associated with a first channel (e.g., channel 0). In an example, the memory dies in the first group of memory dies are daisy-chained together and a first memory die (e.g., memory die 120A) in the first group of memory dies 120 is positioned at or near a center of the PCB 110. In an example, in this configuration, the last memory die (e.g., memory die 120D) may use or implement an on die termination (ODT) when a read operation and/or a write operation is occurring on any of the other memory dies (e.g., memory die 120A, memory die 120B, memory die 120C) in the first group of memory dies 120.

Likewise, memory die 130A, memory die 130B, memory die 130C and memory die 130D form a second group of memory dies 130 and/or are associated with a second channel (e.g., channel 1). Like the first group of memory dies 120, each memory die in the second group of memory dies 130 are daisy-chained together with a first memory die (e.g., memory die 130A) being positioned at or near a center of the PCB 110. Although a four die per channel configuration is shown and described, this is for example purposes only.

In an example, each of the memory dies are flip chip memory dies. In yet another example, the memory dies of the data storage device are NAND memory dies or flip chip NAND memory dies. Additionally, and as shown in FIG. 1A, instead of being vertically stacked, the memory dies are horizontally arranged or aligned on the PCB 110.

The data storage device 100 also includes a controller 140. The controller 140 is communicatively and/or electrically coupled to each of the memory dies using one or more traces. As will be described in greater detail herein, the one or more traces are variable impedance traces. For example, a first portion of each variable impedance trace has a first impedance and a second portion of the variable impedance trace has a second impedance.

In some examples, the impedance of each portion of the variable impedance trace is based, at least in part, on a configuration of one or more metal layers of the PCB 110. Additionally, the impedance of each portion of the variable impedance trace is based, at least in part, on a type of signal provided from and/or to the controller 140.

For example, if the signal transmitted from the controller 140 is a single-ended signal (e.g., a data bus (DQ) signal), the impedance of the first portion of the variable impedance trace is thirty-five ohms (Ω) and the impedance of the second portion of the variable impedance trace is seventy Ω. However, if the signal is a differential signal (e.g., a data strobe (DQS) signal, a complementary data strobe (BDQS) signal, a read enable (RE) signal, or a complementary read enable (BRE) signal), the impedance of the first portion of the variable impedance trace is seventy Ω and the impedance of the second portion of the variable impedance trace is one hundred thirty Ω. Although specific values are given, these are for example purposes only.

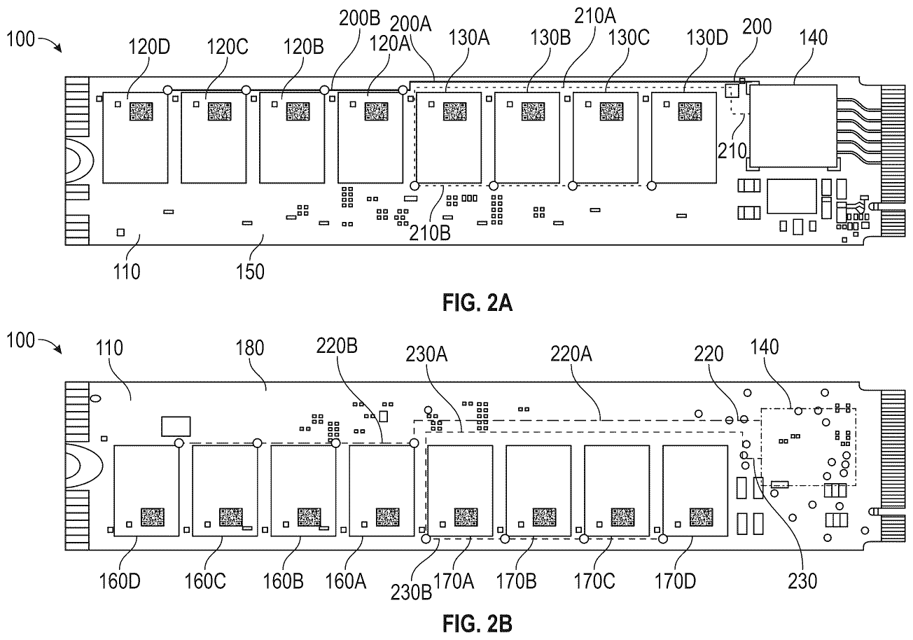

FIG. 2A illustrates a first variable impedance trace 200 coupling the controller 140 to the first group of memory dies of the data storage device 100 and a second variable impedance trace 210 coupling the controller 140 to the second group of memory dies of the data storage device 100 according to an example. In an example, each of the first variable impedance trace 200 and the second variable impedance trace 210 represent multiple variable impedance traces. For example, multiple variable impedance traces couple the controller 140 to each memory die on the first side 150 of the PCB 110 of the data storage device 100.

In an example, the first variable impedance trace 200 has first portion 200A and a second portion 200B. The first portion 200A of the first variable impedance trace 200 extends from the controller 140 to the first memory die in the first group of memory dies 120 (FIG. 1A). For example, the first portion 200A of the first variable impedance trace 200 extends from the controller 140 to memory die 120A.

The second portion 200B of the first variable impedance trace 200 extends from memory die 120A to memory die 120B, to memory die 120C and to memory die 120D. For example, memory die 120A, memory die 120B, memory die 120C and memory die 120D are daisy-chained together with the second portion 200B of the first variable impedance trace 200.

As will be explained in greater detail herein, due to a configuration of one or more metal layers of the PCB 110 of the data storage device 100, the impedance of the first portion 200A of the first variable impedance trace 200 is different (e.g., lower) than the impedance of the second portion 200B of the first variable impedance trace 200.

For example, the impedance of the first portion 200A of the first variable impedance trace 200 is thirty-five Ω when a signal transmitted from the controller 140 is a single-ended signal. However, the impedance of the first portion 200A of the first variable impedance trace 200 is seventy Ω when a signal transmitted from the controller 140 is a differential signal.

Additionally, the impedance of the second portion 200B of the first variable impedance trace 200 is seventy Ω when a signal transmitted from the controller 140 is a single-ended signal and is one hundred thirty Ω when a signal transmitted from the controller 140 is a differential signal.

Likewise, the second variable impedance trace 210 has first portion 210A and a second portion 210B. The first portion 210A of the second variable impedance trace 210 extends from the controller 140 to the first memory die in the second group of memory dies 130 (FIG. 1A). For example, the first portion 210A of the second variable impedance trace 210 extends from the controller 140 to memory die 130A.

The second portion 210B of the second variable impedance trace 210 extends from memory die 130A to memory die 130B, to memory die 130C and to memory die 130D. For example, memory die 130A, memory die 130B, memory die 130C and memory die 130D are daisy-chained together with the second portion 210B of the second variable impedance trace 210.

As with the other examples previously described, and due to a configuration of one or more metal layers of the PCB 110 of the data storage device 100, the impedance of the first portion 210A of the second variable impedance trace 210 is different than the impedance of the second portion 210B of the second variable impedance trace 210.

For example, the impedance of the first portion 210A of the second variable impedance trace 210 is thirty-five Ω when a signal transmitted from the controller 140 is a single-ended signal and is seventy Ω when a signal transmitted from the controller 140 is a differential signal. The impedance of the second portion 210B of the second variable impedance trace 210 is seventy Ω when a signal transmitted from the controller 140 is a single-ended signal and is one hundred thirty Ω when a signal transmitted from the controller 140 is a differential signal.

FIG. 1B illustrates the data storage device 100 of FIG. 1A having a plurality of memory dies horizontally arranged on a second side 180 of the PCB 110 according to an example. For example, the data storage device 100 includes eight memory dies on the second side 180 of the PCB 110—memory die 160A, memory die 160B, memory die 160C, memory die 160D, memory die 170A, memory die 170B, memory die 170C and memory die 170D. Although eight memory dies are shown and described, there may be more than eight memory dies or fewer than eight memory dies on the second side 180 of the PCB 110 of the data storage device 100.

As with the memory dies on the first side 150 of the PCB 110, the plurality of memory dies on the second side 180 of the PCB are arranged in subsets or groups. Further, each group is associated with a particular channel. For example, memory die 160A, memory die 160B, memory die 160C and memory die 160D form a third group of memory dies 160 and/or are associated with a third channel (e.g., channel 2). In an example, a first memory die (e.g., memory die 160A) of the third group of memory dies 160 is positioned at or proximate a center or middle of the PCB 110.

Likewise, memory die 170A, memory die 170B, memory die 170C and memory die 170D form a fourth group of memory dies 170 and/or are associated with a fourth channel (e.g., channel 3). As with the other examples described herein, a first memory die (e.g., memory die 170A) of the fourth group of memory dies 170 is positioned at or proximate a center or middle of the PCB 110.

The memory dies on the second side 180 of the PCB 110 are also communicatively and/or electrically coupled to the controller 140. For example, one or more variable impedance traces extend from the controller 140 to the second side 180 of the PCB 110 (e.g., using a via or other opening) and to each of the memory dies. As with the other examples described herein, the variable impedance traces that couple the controller 140 to the memory dies on the second side 180 of the PCB 110 have different portions and each portion have, or are otherwise associated with, a different impedance.

For example, and referring to FIG. 2B, FIG. 2B illustrates a third variable impedance trace 220 coupling the controller 140 to the third group of memory dies of the data storage device 100 and a fourth variable impedance trace 230 coupling the controller 140 to the fourth group of memory dies of the data storage device 100 according to an example. In an example, each of the third variable impedance trace 220 and the fourth variable impedance trace 230 represent multiple traces. For example, multiple variable impedance traces couple the controller 140 to each memory die on the second side 180 of the PCB 110 of the data storage device 100.

As with the example shown and described with respect to FIG. 2B, the third variable impedance trace 220 has first portion 220A and a second portion 220B. The first portion 220A of the third variable impedance trace 220 extends from the controller 140 to memory die 160A. The second portion 220B of the third variable impedance trace 220 extends from memory die 160A to memory die 160B, to memory die 160C and to memory die 160D. For example, memory die 160A, memory die 160B, memory die 160C and memory die 160D are coupled in series and/or are daisy-chained together with the second portion 220B of the third variable impedance trace 220.

Due to a configuration of one or more metal layers of the PCB 110 of the data storage device, the impedance of the first portion 220A of the third variable impedance trace 220 is different (e.g., lower) than the impedance of the second portion 220B of the third variable impedance trace 220.

For example, the impedance of the first portion 220A of the third variable impedance trace 220 is thirty-five Ω when a signal transmitted from the controller 140 is a single-ended signal. However, the impedance of the first portion 220A of the third variable impedance trace 220 is seventy Ω when a signal transmitted from the controller 140 is a differential signal. Additionally, the impedance of the second portion 220B of the third variable impedance trace 220 is seventy Ω when a signal transmitted from the controller 140 is a single-ended signal and is one hundred thirty Ω when a signal transmitted from the controller 140 is a differential signal.

Likewise, the fourth variable impedance trace 230 has first portion 230A and a second portion 230B. The first portion 230A of the fourth variable impedance trace 230 extends from the controller 140 to memory die 170A. The second portion 230B of the fourth variable impedance trace 230 extends from memory die 170A to memory die 170B, to memory die 170C and to memory die 170D. For example, memory die 170A, memory die 170B, memory die 170C and memory die 170D are coupled in series and/or are daisy-chained together with the second portion 230B of the fourth variable impedance trace 230.

As with the other examples previously described, and due to a configuration of one or more metal layers of the PCB 110 of the data storage device 100, the impedance of the first portion 230A of the fourth variable impedance trace 230 is different than the impedance of the second portion 230B of the fourth variable impedance trace 230.

For example, the impedance of the first portion 230A of the fourth variable impedance trace 230 is thirty-five Ω when a signal transmitted from the controller 140 is a single-ended signal and is seventy Ω when a signal transmitted from the controller 140 is a differential signal. The impedance of the second portion 230B of the fourth variable impedance trace 230 is seventy Ω when a signal transmitted from the controller 140 is a single-ended signal and is one hundred thirty Ω when a signal transmitted from the controller 140 is a differential signal.

In some examples, and in order to further increase the impedance on at least a portion of the variable impedance traces of the data storage device 100, one or more discrete components (e.g., a resistor) is associated with the one or more of the variable impedance traces. In an example, the one or more discrete components add a series resistance to the second portion of each of the variable impedance traces.

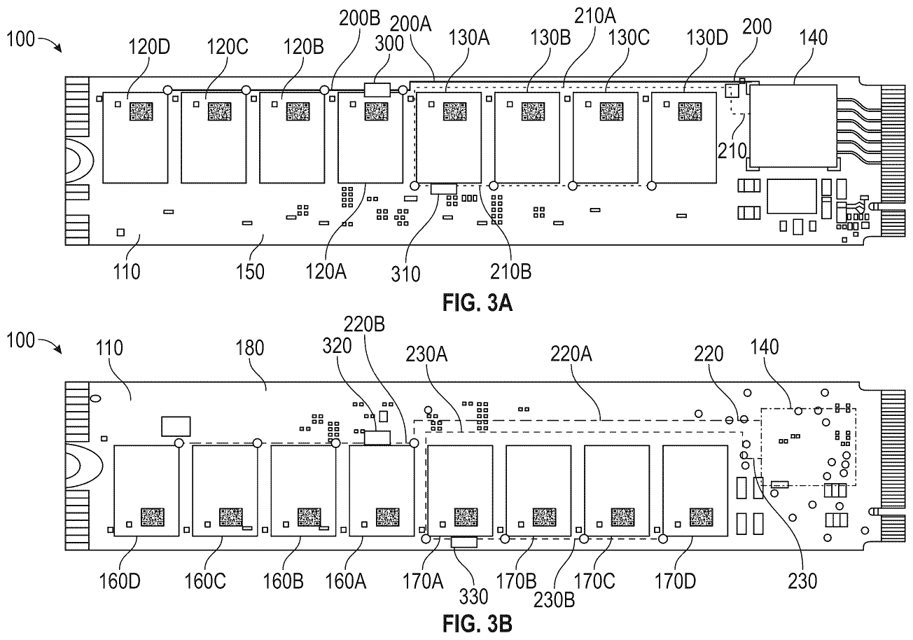

FIG. 3A illustrates a first discrete component 300 being added to, or associated with, the first variable impedance trace 200 of the data storage device 100 of FIG. 2A and a second discrete component 310 being added to, or associated with, the second variable impedance trace 210 of the data storage device 100 of FIG. 2A. Likewise, FIG. 3B illustrates a third discrete component 320 being added to, or associated with, the third variable impedance trace 230 of the data storage device 100 of FIG. 2B and a fourth discrete component 330 being added to, or associated with, the fourth variable impedance trace 230 of the data storage device 100 of FIG. 2B according to an example.

As previously discussed, the discrete component is a resistor. Although a resistor is specifically mentioned, other components may be used to increase the resistance on, or otherwise associated with, the second portions of the various variable impedance traces. In an example, the discrete component increases the resistance on the second portions of the various variable impedances traces by at least five Ω (e.g., 5.1 Ω). In an example, the discrete component suppresses any reflections that may occur on the first memory die in each of the groups of memory dies.

As shown in FIG. 3A, the first discrete component 300 is provided between the memory die 120A and memory die 120B. Likewise, the second discrete component 310 is provided between the memory die 130A and the memory die 130B. As shown in FIG. 3B, the third discrete component 320 is provided between the memory die 160A and memory die 160B and the fourth discrete component 330 is provided between the memory die 170A and the memory die 170B.

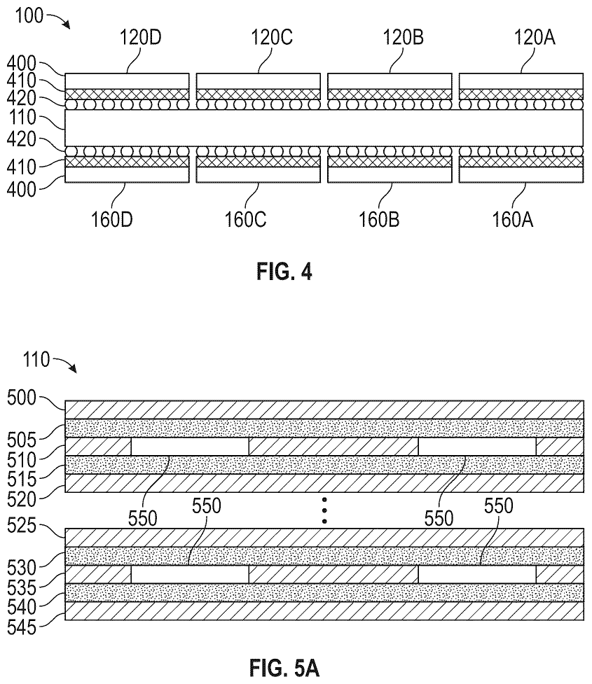

FIG. 4 illustrates a partial side view of the data storage device 100 of FIG. 1A according to an example. As previously discussed, the data storage device 100 includes a plurality of memory dies horizontally arranged on a first side of the PCB 110 and a plurality of memory dies horizontally arranged on a second side of the PCB 110. For example, memory die 120A, memory die 120B, memory die 120C and memory die 120D are horizontally arranged on the first side of the PCB 110 and memory die 160A, memory die 160B, memory die 160C and memory die 160D are horizontally arranged on the second side of the PCB 110. In an example, each memory die is a flip chip NAND memory die. As such, each memory die includes a NAND die 400 and a redistribution layer (RDL) 410. In an example, various RDL bumps 420 are used to couple each memory die to the PCB 110.

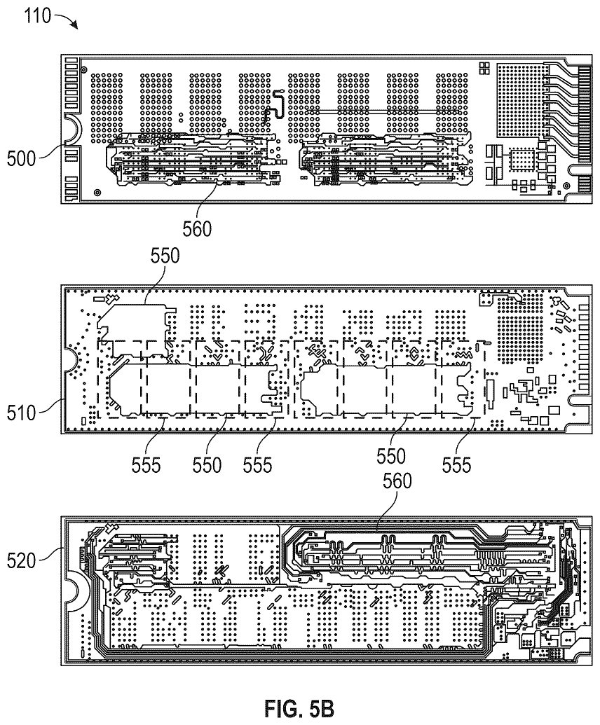

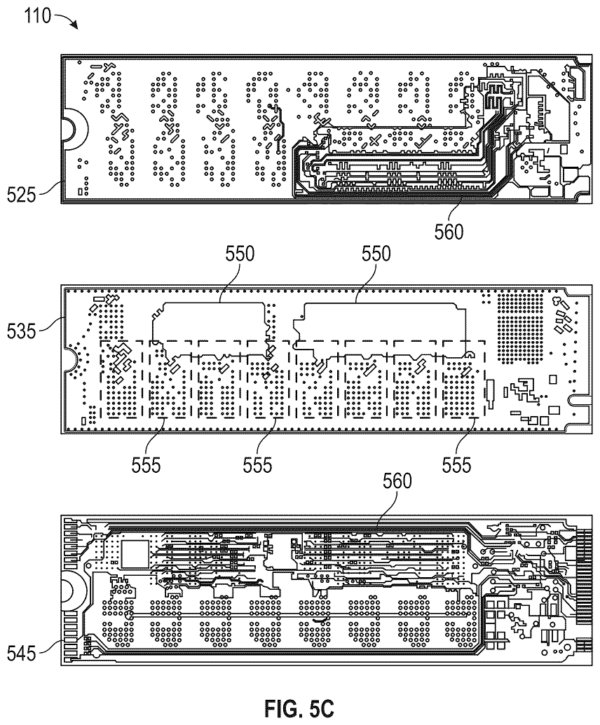

FIG. 5A illustrates a side view of the PCB 110 of the data storage device 100 of FIG. 1A according to an example. In an example, the PCB 110 includes a number of layers. For example, the PCB 110 includes a first metal layer 500 on which a first plurality of memory dies are mounted. The PCB 110 also includes a first dielectric layer 505, a second metal layer 510, a second dielectric layer 515 and a third metal layer 520.

In an example, the PCB 110 also includes a fourth metal layer 525, a third dielectric layer 530, a fifth metal layer 535, a fourth dielectric layer 540 and a sixth metal layer 545. In an example, a second plurality of memory dies are mounted on the sixth metal layer 545 of the PCB 110. Although ten layers are shown and described, the PCB 110 may include any number of layers including any number of dielectric layers and/or metal layers.

In order to increase the impedance of the various traces that are embedded in or are otherwise associated with the PCB 110, the second metal layer 510 and the fifth metal layer 535 include various openings 550 or gaps. The openings 550 are “cut out” areas within the second metal layer 510 and the fifth metal layer 535 that are open or otherwise have no metal (or less metal when compared with other areas of the metal layer). In an example, the third metal layer 520 and the fourth metal layer 525 act as ground reference layers (e.g., for the second metal layer 510 and/or the fifth metal layer 535).

In an example, each opening 550 extends, at least partially, across locations associated with each of the memory dies. For example, the openings 550 extend parallel to the various variable impedance traces (or different portions of the variable impedance traces (e.g., the second portions)) that are provided on and/or within the first metal layer 500 and/or the sixth metal layer 545.

FIG. 5B illustrates the various metal layers of the PCB 110 of FIG. 5A according to an example. In an example, the various metal layers are used in the PCB 110 of the data storage device 100 shown and described with respect to FIG. 1A. As shown in FIG. 5B, the second metal layer 510 includes openings 555 that extend at least partially across locations of the memory dies 580 (shown by the dashed rectangles) that are coupled to the first metal layer 500 of the PCB 110. Additionally, an area of each opening 570 is based, at least in part, on an area that is occupied by the variable impedance traces 560 provided on the first metal layer 500 and/or the third metal layer 520 whose impedance is to be increased and/or based on the signal type (e.g., single-ended or differential) being transmitted across the various variable impedances traces.

FIG. 5C illustrates the various metal layers of the PCB 110 of FIG. 5A according to an example. In an example, the various metal layers are used in the PCB 110 of the data storage device 100 shown and described with respect to FIG. 1B. As shown in FIG. 5C, the fifth metal layer 535 includes openings 550 that extend at least partially across locations of the memory dies 555 (shown by the dashed rectangles) that are coupled to the sixth metal layer 545 of the PCB 110. Additionally, an area of each opening 550 is based, at least in part, on an area that is occupied by the variable impedance traces 560 provided on the sixth metal layer 545 and/or the fourth metal layer 525 whose impedance is to be increased and/or based on the signal type (e.g., single-ended or differential) being transmitted across the various variable impedances traces.

Although the examples described herein are directed to a data storage device and memory dies, the concepts described herein may be used with a number of different semiconductor packages having a number of different integrated circuits (e.g., flip chip integrated circuits) that are horizontally arranged on a PCB of the semiconductor package.

Additionally, and although memory dies are specifically mentioned, the data storage device described herein may include any non-volatile memory device, storage device, storage elements or storage medium including NAND flash memory cells and/or NOR flash memory cells.

The memory cells of the various memory dies can take the form of solid-state (e.g., flash) memory cells and can be one-time programmable, few-times programmable, or many-times programmable. Additionally, the memory cells may be single-level cells (SLCs), multi-level cells (MLCs), triple-level cells (TLCs), quad-level cells (QLCs), penta-level cells (PLCs), and/or use any other memory technologies. The memory cells may be arranged in a two-dimensional configuration or a three-dimensional configuration.

Based on the above, examples of the present disclosure describe a semiconductor package, comprising: a printed circuit board (PCB); a controller mounted on the PCB; a plurality of flip chip semiconductor dies mounted on the PCB; a plurality of variable impedance traces electrically coupling the controller to the plurality of flip chip semiconductor dies; and a component positioned between a first flip chip semiconductor die in the plurality of flip chip semiconductor dies and a second flip chip semiconductor die in the plurality of flip chip semiconductor dies, the component increasing a resistance of at least a portion of at least one variable impedance trace of the plurality of variable impedance traces between the first flip chip semiconductor die and the second flip chip semiconductor die. In an example, the PCB comprises: a first layer; a second layer; and a third layer, wherein the third layer includes at least one gap positioned below at least one of the plurality of the variable impedance traces. In an example, the semiconductor package also includes a ground reference layer provided beneath the third layer. In an example, the plurality of flip chip semiconductor dies are a first plurality of flip chip semiconductor dies; the plurality of variable impedance traces are a first plurality of variable impedance traces; and electrically coupling the controller to the plurality of flip chip semiconductor dies; and the component is a first component, and wherein the semiconductor package further comprises: a second plurality of flip chip semiconductor dies mounted on the PCB; a second plurality of variable impedance traces electrically coupling the controller to the second plurality of flip chip semiconductor dies; and a second component positioned between a first flip chip semiconductor die in the second plurality of flip chip semiconductor dies and a second flip chip semiconductor die in the second plurality of flip chip semiconductor dies, the second component increasing a resistance of the second plurality of variable impedance traces between the first flip chip semiconductor die and the second flip chip semiconductor die. In an example, the first plurality of flip chip semiconductor dies is mounted on a first surface of the PCB and the second plurality of flip chip semiconductor dies is mounted on a second surface of the PCB. In an example, an impedance of a first portion of at least one variable impedance trace of the plurality of variable impedance traces has a first impedance and a second portion of the at least one variable impedance trace of the plurality of variable impedance traces has a second impedance that is greater than the first impedance. In an example, the first impedance is thirty-five ohms and the second impedance is seventy ohms for single ended signals. In an example, the first impedance is seventy ohms and the second impedance is one hundred thirty ohms for differential signals. In an example, the first impedance is associated with a first flip chip semiconductor die in the plurality of flip chip semiconductor dies and the second impedance is associated with remaining flip chip semiconductor dies in the plurality of flip chip semiconductor dies.

Examples also describe a data storage device, comprising: a printed circuit board (PCB) having a plurality of metal layers, wherein at least one metal layer of the plurality of metal layers includes one or more gaps; a controller mounted on the PCB; a plurality of memory dies horizontally arranged on the PCB; a plurality of traces electrically coupling the controller to the plurality of memory dies and at least partially positioned over the one or more gaps; and a resistor positioned between a first memory die in the plurality of memory dies and a second memory die in the plurality of memory dies. In an example, the plurality memory dies are flip chip memory dies. In an example, a first subset of the plurality of memory dies is mounted on a first surface of the PCB and a second subset of the plurality of memory dies is mounted on a second surface of the PCB. In an example, an impedance of a first portion of at least one trace of the plurality of traces has a first impedance and a second portion of the at least one trace of the plurality of traces has a second impedance that is greater than the first impedance. In an example, the first impedance is thirty-five ohms and the second impedance is seventy ohms for single ended signals. In an example, the first impedance is seventy ohms and the second impedance is one hundred thirty ohms for differential signals.

Still other examples describe a data storage device, comprising: a printed circuit board (PCB); a controller means mounted on the PCB; a plurality of flip chip data storage means arranged on the PCB; a plurality of variable impedance signal means electrically coupling the controller means to the plurality of flip chip data storage means; and a resistance means positioned between a first flip chip storage means in the plurality of flip chip storage means and a second flip chip storage means in the plurality of flip chip storage means. In an example, the PCB comprises: a first layer; a second layer; and a third layer, wherein the third layer includes at least one gap positioned below at least one of the plurality of the variable impedance signal means. In an example, a first subset of the plurality of flip chip data storage means is mounted on a first surface of the PCB and a second subset of the plurality of flip chip data storage means is mounted on a second surface of the PCB. In an example, an impedance of a first portion of at least one variable impedance signal means has a first impedance and a second portion of the at least one variable impedance signal means has a second impedance that is greater than the first impedance. In an example, the first impedance and the second impedance is based, at least in part, on a type of signal provided by the controller means.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an example with a particular set of features. Having been provided with the description and illustration of the present disclosure, one skilled in the art may envision variations, modifications, and alternate aspects falling within the spirit of the broader aspects of the general inventive concept embodied in this disclosure that do not depart from the broader scope of the claimed disclosure.

Aspects of the present disclosure have been described above with reference to schematic flowchart diagrams and/or schematic block diagrams of methods, apparatuses, systems, and computer program products according to examples of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A semiconductor package, comprising:
a printed circuit board (PCB);
a controller mounted on the PCB;
a plurality of flip chip semiconductor dies mounted on the PCB;
a plurality of variable impedance traces electrically coupling the controller to the plurality of flip chip semiconductor dies; and
a component positioned between a first flip chip semiconductor die in the plurality of flip chip semiconductor dies and a second flip chip semiconductor die in the plurality of flip chip semiconductor dies, the component increasing a resistance of at least a portion of at least one variable impedance trace of the plurality of variable impedance traces between the first flip chip semiconductor die and the second flip chip semiconductor die.

2. The semiconductor package of claim 1, wherein the PCB comprises:
a first layer;
a second layer; and
a third layer, wherein the third layer includes at least one gap positioned below at least one of the plurality of the variable impedance traces.

3. The semiconductor package of claim 2, further comprising a ground reference layer provided beneath the third layer.

4. The semiconductor package of claim 1, wherein:
the plurality of flip chip semiconductor dies are a first plurality of flip chip semiconductor dies;
the plurality of variable impedance traces are a first plurality of variable impedance traces; and electrically coupling the controller to the plurality of flip chip semiconductor dies; and
the component is a first component, and wherein the semiconductor package further comprises:
a second plurality of flip chip semiconductor dies mounted on the PCB;
a second plurality of variable impedance traces electrically coupling the controller to the second plurality of flip chip semiconductor dies; and
a second component positioned between a first flip chip semiconductor die in the second plurality of flip chip semiconductor dies and a second flip chip semiconductor die in the second plurality of flip chip semiconductor dies, the second component increasing a resistance of the second plurality of variable impedance traces between the first flip chip semiconductor die and the second flip chip semiconductor die.

5. The semiconductor package of claim 4, wherein the first plurality of flip chip semiconductor dies is mounted on a first surface of the PCB and the second plurality of flip chip semiconductor dies is mounted on a second surface of the PCB.

6. The semiconductor package of claim 1, wherein an impedance of a first portion of at least one variable impedance trace of the plurality of variable impedance traces has a first impedance and a second portion of the at least one variable impedance trace of the plurality of variable impedance traces has a second impedance that is greater than the first impedance.

7. The semiconductor package of claim 6, wherein the first impedance is thirty-five ohms and the second impedance is seventy ohms for single ended signals.

8. The semiconductor package of claim 6, wherein the first impedance is seventy ohms and the second impedance is one hundred thirty ohms for differential signals.

9. The semiconductor package of claim 6, wherein the first impedance is associated with a first flip chip semiconductor die in the plurality of flip chip semiconductor dies and the second impedance is associated with remaining flip chip semiconductor dies in the plurality of flip chip semiconductor dies.

10. A data storage device, comprising:
a printed circuit board (PCB) having a plurality of metal layers, wherein at least one metal layer of the plurality of metal layers includes one or more gaps;
a controller mounted on the PCB;
a plurality of memory dies horizontally arranged on the PCB;
a plurality of traces electrically coupling the controller to the plurality of memory dies and at least partially positioned over the one or more gaps; and
a resistor positioned between a first memory die in the plurality of memory dies and a second memory die in the plurality of memory dies.

11. The data storage device of claim 10, wherein the plurality memory dies are flip chip memory dies.

12. The data storage device of claim 10, wherein a first subset of the plurality of memory dies is mounted on a first surface of the PCB and a second subset of the plurality of memory dies is mounted on a second surface of the PCB.

13. The data storage device of claim 10, wherein an impedance of a first portion of at least one trace of the plurality of traces has a first impedance and a second portion of the at least one trace of the plurality of traces has a second impedance that is greater than the first impedance.

14. The data storage device of claim 13, wherein the first impedance is thirty-five ohms and the second impedance is seventy ohms for single ended signals.

15. The data storage device of claim 13, wherein the first impedance is seventy ohms and the second impedance is one hundred thirty ohms for differential signals.

16. A data storage device, comprising:
a printed circuit board (PCB);
a controller means mounted on the PCB;
a plurality of flip chip data storage means arranged on the PCB;
a plurality of variable impedance signal means electrically coupling the controller means to the plurality of flip chip data storage means; and
a resistance means positioned between a first flip chip storage means in the plurality of flip chip storage means and a second flip chip storage means in the plurality of flip chip storage means.

17. The data storage device of claim 16, wherein the PCB comprises:
a first layer;
a second layer; and
a third layer, wherein the third layer includes at least one gap positioned below at least one of the plurality of the variable impedance signal means.

18. The data storage device of claim 16, wherein a first subset of the plurality of flip chip data storage means is mounted on a first surface of the PCB and a second subset of the plurality of flip chip data storage means is mounted on a second surface of the PCB.

19. The data storage device of claim 16, wherein an impedance of a first portion of at least one variable impedance signal means has a first impedance and a second portion of the at least one variable impedance signal means has a second impedance that is greater than the first impedance.

20. The data storage device of claim 19, wherein the first impedance and the second impedance is based, at least in part, on a type of signal provided by the controller means.
